(19) United States
(12) Patent Application Publication
(10) Pub. No.: US 2024/0237330 A1
(43) Pub. Date: Jul. 11, 2024

(54) Array Of Capacitors, Array Of Memory Cells, And Methods Used In Forming An Array Of Capacitors

(71) Applicant: Micron Technology, Inc., Boise, ID (US)

(72) Inventors: Jordan D. Greenlee, Nampa, ID (US); Andrea Gotti, Boise, ID (US); David McShannon, Meridian, ID (US); Silvia Borsari, Boise, ID (US)

(73) Assignee: Micron Technology, Inc., Boise, ID (US)

(21) Appl. No.: 18/407,675

(22) Filed: Jan. 9, 2024

Related U.S. Application Data
(60) Provisional application No. 63/438,304, filed on Jan. 11, 2023.

(51) Int. Cl. H10B 12/00; G11C 5/06

(52) U.S. Cl. CPC H10B 12/31; G11C 5/063; H01L 28/91; H10B 12/482; H10B 12/488

(57) ABSTRACT

A method used in forming an array of capacitors comprises forming horizontally-spaced openings into sacrificial material and through insulative material that is between a top and bottom of the sacrificial material. The insulative material at least predominately comprises at least one of a silicon nitride, a silicon boronitride, and a silicon carbonitride. The insulative material with horizontally-spaced openings there-through comprises an insulative horizontal lattice. An insulative lining is deposited within the horizontally-spaced openings and directly above the sacrificial material. The insulative lining at least predominately comprises at least one of a silicon oxide and a silicon oxynitride. During the depositing, the insulative lining is intermittently exposed to a nitrogen-containing plasma. First capacitor electrodes that are individually within individual of the horizontally-spaced openings are formed laterally over the insulative lining that is in the horizontally-spaced openings. The sacrificial material is removed and a capacitor insulator is formed over the first capacitor electrodes and the insulative horizontal lattice. Second-capacitor-electrode material is formed over the capacitor insulator. Structure independent of method is disclosed.

### TECHNICAL FIELD

Embodiments disclosed herein pertain to arrays of capacitors, to arrays of memory cells, and to methods used in forming an array of capacitors.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The digitlines may conductively interconnect memory cells along columns of the array, and the access lines may conductively interconnect memory cells along rows of the array. Each memory cell may be uniquely addressed through the combination of a digitline and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A capacitor is one type of electronic component that may be used in a memory cell. A capacitor has two electrical conductors separated by electrically insulating material. Energy as an electric field may be electrostatically stored within such material. Depending on composition of the insulator material, that stored field will be volatile or non-volatile. For example, a capacitor insulator material including only SiO₂ will be volatile. One type of non-volatile capacitor is a ferroelectric capacitor which has ferroelectric material as at least part of the insulating material. Ferroelectric materials are characterized by having two stable polarized states and thereby can comprise programmable material of a capacitor and/or memory cell. The polarization state of the ferroelectric material can be changed by application of suitable programming voltages and remains after removal of the programming voltage (at least for a time). Each polarization state has a different charge-stored capacitance from the other, and which ideally can be used to write (i.e., store) and read a memory state without reversing the polarization state until such is desired to be reversed. Less desirable, in some memory having ferroelectric capacitors the act of reading the memory state can reverse the polarization. Accordingly, upon determining the polarization state, a re-write of the memory cell is conducted to put the memory cell into the pre-read state immediately after its determination. Regardless, a memory cell incorporating a ferroelectric capacitor ideally is non-volatile due to the bi-stable characteristics of the ferroelectric material that forms a part of the capacitor. Other programmable materials may be used as a capacitor insulator to render capacitors non-volatile.

A field effect transistor is another type of electronic component that may be used in a memory cell. These transistors comprise a pair of conductive source/drain regions having a semiconductive channel region there-between. A conductive gate is adjacent the channel region and separated therefrom by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate. Regardless, the gate insulator may be programmable, for example being ferroelectric.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIG. 3 is a diagrammatic perspective view of a portion of a substrate in process in accordance with an embodiment of the invention.

FIGS. 4-15 are diagrammatic sequential sectional, expanded, enlarged, perspective, and/or partial views of the schematic of FIG. 1 and the construction of FIG. 3, or portions thereof, or partial hybrid schematics or partial schematics thereof, and/or alternate embodiments in process in accordance with some embodiments of the invention.

### DETAILED DESCRIPTION OF EXAMPLE EMBODIMENTS

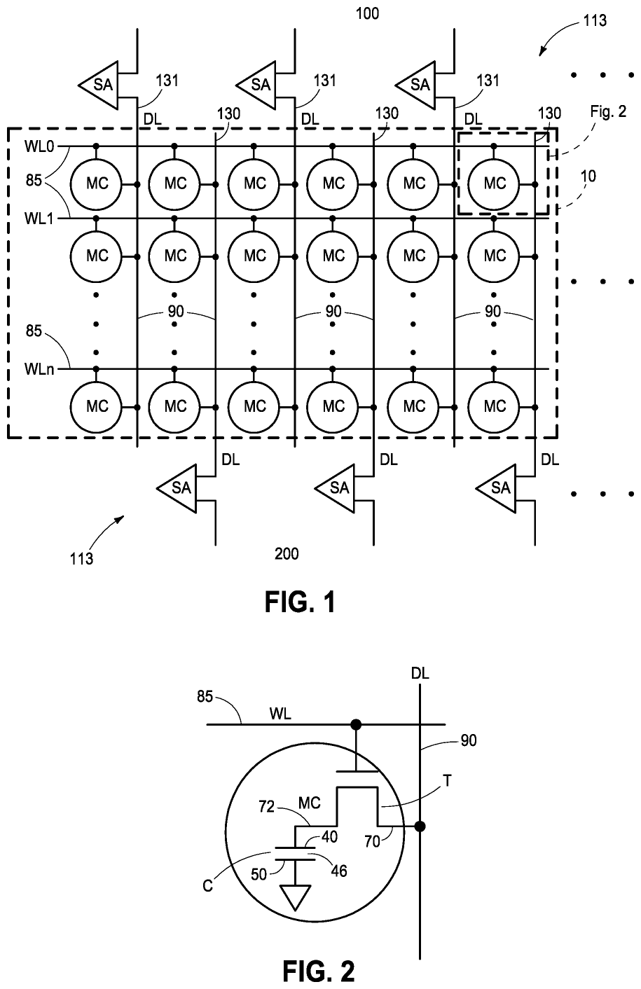

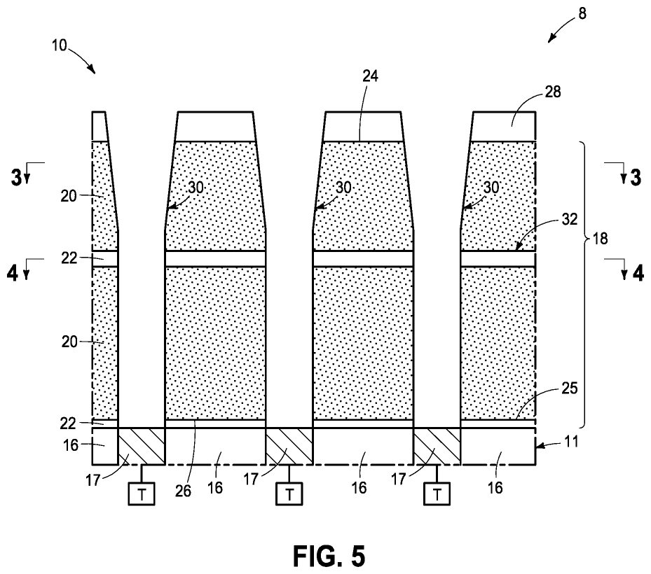

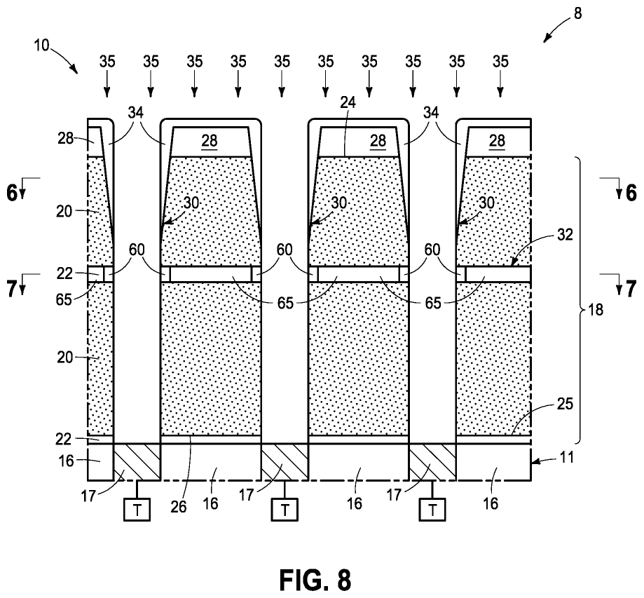

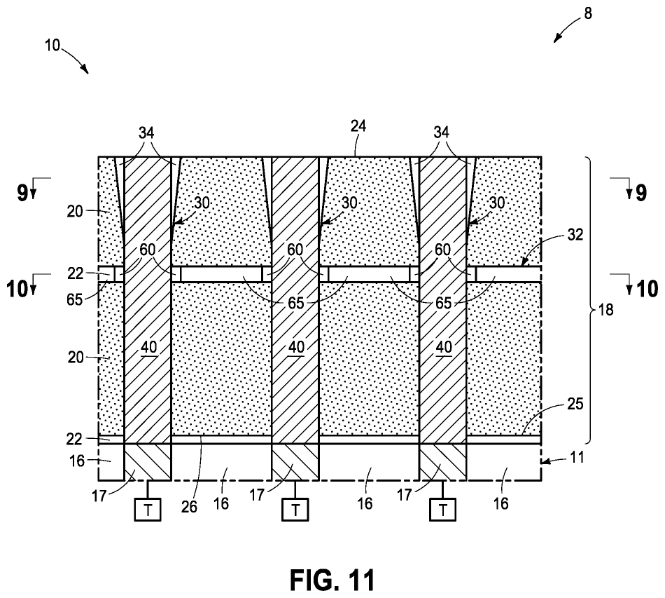

Embodiments of the invention include methods used in forming an array of capacitors, for example as may be used in memory or other integrated circuitry. Embodiments of the invention also encompass methods used in forming an array of memory cells, for example comprising a plurality of capacitors that are above a plurality of transistors. Embodiments of the invention also encompass an array of capacitors and an array of memory cells independent of method of manufacture. Example embodiments of methods of forming an array of memory cells are described with reference to FIGS. 1-15.

One example prior art schematic diagram of DRAM circuitry, and in accordance with an embodiment of the invention, is shown in FIGS. 1 and 2. FIG. 2 shows example memory cells MC individually comprising a transistor T comprising a pair of source/drain regions and a capacitor C comprising a first capacitor electrode, a second capacitor electrode, and a capacitor insulator there-between. One electrode of capacitor C is directly electrically coupled to a suitable potential (e.g., ground) and the other capacitor electrode is contacted with or comprises one of the source/drain regions of transistor T. The other source/drain region of transistor T is electrically coupled (e.g., directly) with a digitline 130 or 131 (also individually designated as DL). The gate of transistor T is directly electrically coupled with (e.g., comprises part of) a wordline WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Accordingly, and in one embodiment, transistors T are arrayed in rows 85 and columns 90 and a gateline (e.g., WL) interconnects multiple of transistors T along individual of the rows. A digitline DL interconnects multiple of transistors T along individual of the columns.

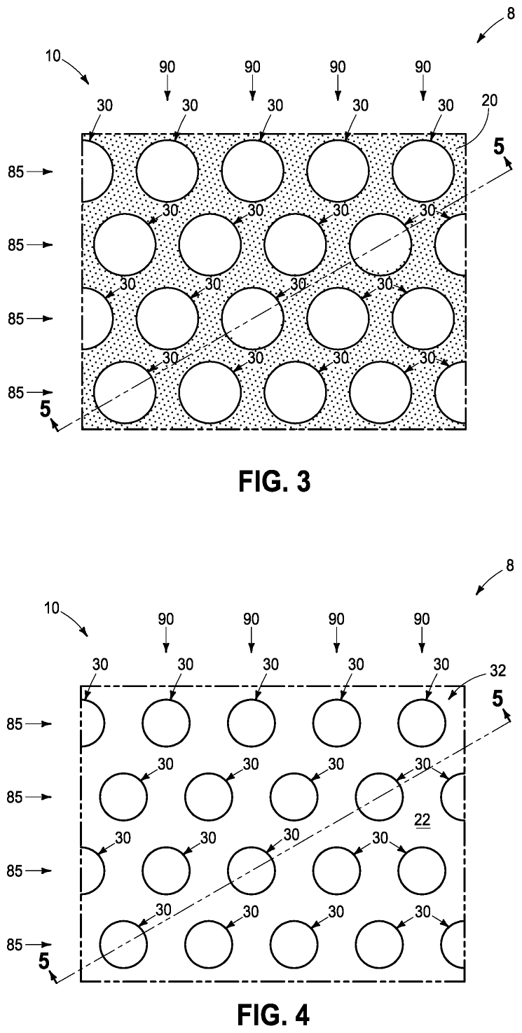

Referring to FIGS. 3-5, such show part of a construction 8 comprising array or array area 10 in which an array of capacitors will be fabricated. Construction 8 comprises a base substrate 11 having any one or more of conductive/conductor/conducting, semiconductive/semiconductor/semiconducting, or insulative/insulator/insulating (i.e., electrically herein) materials. Materials may be aside, elevationally inward, or elevationally outward of the FIGS. 3 -5-depicted materials. For example, other partially or wholly fabricated components of integrated circuitry may be provided somewhere above, about, or within a base substrate (not shown). Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array.

Transistors T (e.g., access devices) are schematically shown in FIG. 3 and may be formed as part of base substrate 11. By way of example only, such may comprise field effect transistors for controlling access to individual capacitors, for example in DRAM circuitry where a transistor T and a capacitor C (not yet formed) comprise components of a single memory cell (e.g., a one transistor, one capacitor [1T/1C] memory cell). However, other memory and non-memory circuitry are contemplated and whether existing or yet-to-be-developed. Example base substrate 11 is shown as comprising insulative material 16 (e.g., doped and/or undoped silicon dioxide) having conductive vias 17 extending there-through to a transistor T. One of the source/drain regions of the pair of source/drain regions of individual transistors T is electrically coupled (e.g., directly) with individual digitlines DL. The other of the source/drain regions of the pair of source/drain regions of individual transistors T is electrically coupled (e.g., directly) with one of the capacitor electrodes (e.g., herein the first capacitor electrode; e.g., through individual conductive vias 17).

A stack 18 has been formed directly above base substrate 11 and comprises sacrificial material 20 and insulative material 22 (e.g., a continuous layer thereof at least initially) that is between a top 24 and a bottom 26 of sacrificial material 20. In one embodiment, insulative material 22 at least predominately (i.e., more than 50% up to and including 100% by volume) comprises at least one of a silicon nitride, a silicon boronitride, and a silicon carbonitride (i.e., regardless of stoichiometry/whether being stoichiometric). By way of example only, only one layer of insulative material 22 is shown between top 24 and bottom 26 and one or more additional such layers of insulative material 22 may be provided there-between (not shown). A layer 25 of insulative material 22 may also be below sacrificial material 20, as shown. Such may be of the same or different thickness as/from that of insulative material 22 there-above. Sacrificial material 20 and insulative material 22 are ideally of etchably-different-compositions relative one another. Example sacrificial materials 20 include doped and undoped silicon dioxide and doped and undoped polysilicon. A hard-masking material 28 (e.g., silicon dioxide) may be atop stack 18 as shown.

Horizontally-spaced openings 30 have been formed into sacrificial material 20 and through insulative material 22 that is between top 24 and bottom 26, for example by anisotropic etching. Openings 30 have also been formed through hard-masking material 28 (when present) and through layer 25 to conductive vias 17 (when present). Insulative material 22 that is between top 24 and bottom 26 with openings 30 there-through comprises an insulative horizontal lattice 32. More such lattices may be formed if one or more layers of insulative material 22 is/are between top 24 and bottom 26 (not shown). In one embodiment, insulative horizontal lattice 32 and insulative material 22 thereof at least predominately comprise at least two of the silicon nitride, the silicon boronitride, and the silicon carbonitride. In one embodiment, insulative horizontal lattice 32 and insulative material 22 thereof at least predominately comprise the silicon nitride, in one embodiment the silicon boronitride, and in one embodiment the silicon carbonitride. In one such latter embodiment, carbon content in the silicon carbonitride is 0.1 atomic percent to 30.0 atomic percent and in one such embodiment is 5.0 atomic percent to 7.0 atomic percent. Openings 30 may taper inwardly and/or outwardly moving deeper into stack 18 (desirably or as an artifact of manufacture). Example openings 30 are shown as being widest at tops thereof and tapering inwardly over only a portion of the height of such openings (e.g., as an undesired artifact of manufacture).

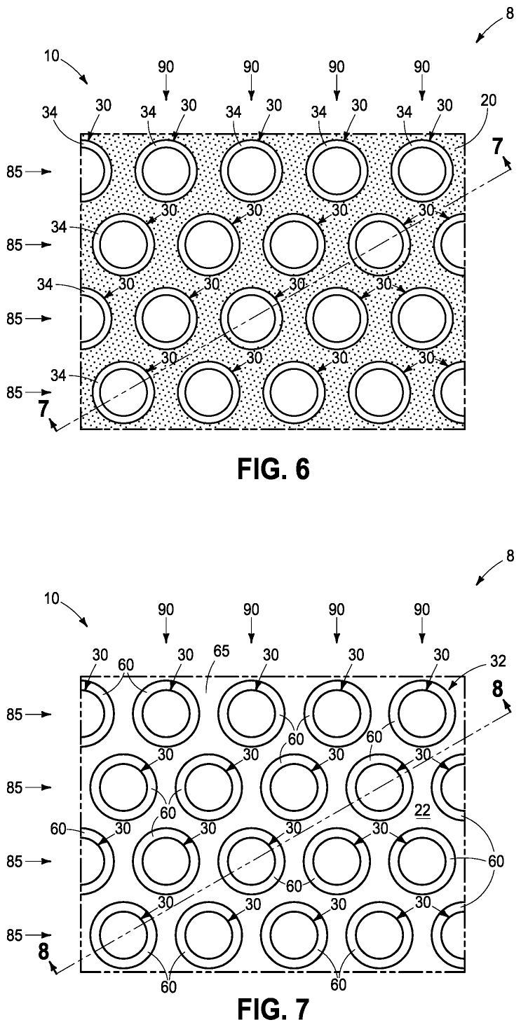

Referring to FIGS. 6-8, an insulative lining 34 has been deposited within horizontally-spaced openings 30 and directly above sacrificial material 20. Insulative lining 34 at least predominately comprises at least one of a silicon oxide and a silicon oxynitride (i.e., regardless of stoichiometry/whether being stoichiometric; e.g., SiO₂ being one silicon oxide). In one embodiment, insulative lining 34 at least predominately comprises the silicon oxide and in one embodiment at least predominately comprises the silicon oxynitride. In one embodiment, insulative lining 34 is not deposited aside insulative horizontal lattice 32 (as shown) and in another embodiment is deposited aside insulative horizontal lattice 32 (not shown). Regardless, during the depositing, insulative lining 34 is intermittently exposed to a nitrogen-containing plasma, for example as is intended to be indicated by downwardly-directed arrows 35. Ideally, and in one embodiment, the intermittently exposing results in less of insulative lining 34 being deposited directly above sacrificial material 20 than would otherwise occur under identical depositing conditions but for the intermittently exposing. Example manners of depositing insulative lining 34 comprise chemical vapor deposition and atomic layer deposition, with or without plasma. An example nitrogen-containing plasma can be derived from one or more of N₂, NH₃, NF₃, NOₓ (e.g., in combination with a non-nitrogen-containing inert gas such as Ar). Example conditions during the intermittent exposing include substrate temperature of 0° C. to 1,000° C. and chamber pressure of 1 mTorr to 1 Torr.

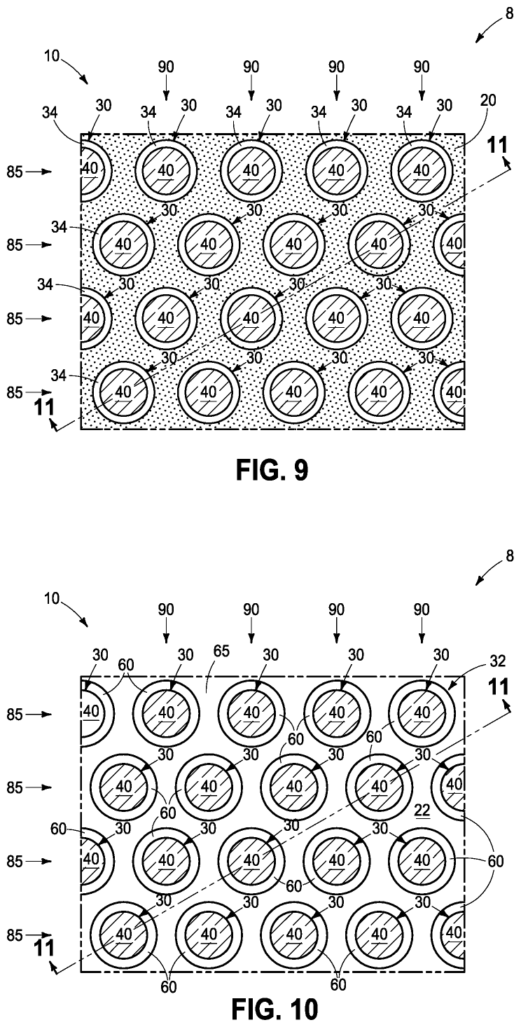

Referring to FIGS. 9-11, first capacitor electrodes 40 have been formed and that are individually within individual of horizontally-spaced openings 30 laterally over insulative lining 34 that is therein. Insulative lining 34 and hard-masking material 28 (not shown) that were directly above sacrificial material 20 may be removed in the process, as shown.

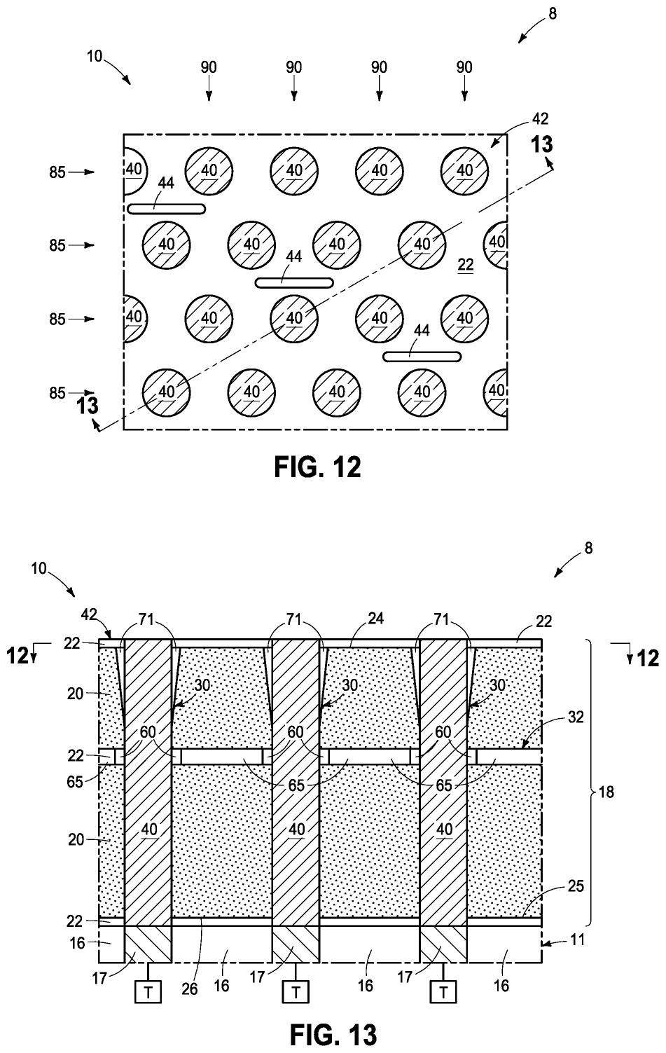

Referring to FIGS. 12 and 13, and in one embodiment, all of insulative lining 34 (not shown) has been removed (e.g., leaving void space 71). Such may occur, for example, by isotropic etching selectively relative to first capacitor electrodes 40. Where, for example, insulative lining 34 comprises undoped silicon dioxide and sacrificial material 20 comprises boron and/or phosphorus-doped silicon dioxide, an example isotropic etching chemistry primarily includes HF and H₂O and using such may etch insulative lining 34 faster than sacrificial material 20. Thereafter, and in one embodiment, an upper insulative lattice 42 (e.g., comprising insulative material 22) has been formed atop sacrificial material 20. Such may be of the same thickness or of different thickness from that/those of insulative horizontal lattice 32 and/or layer 25.

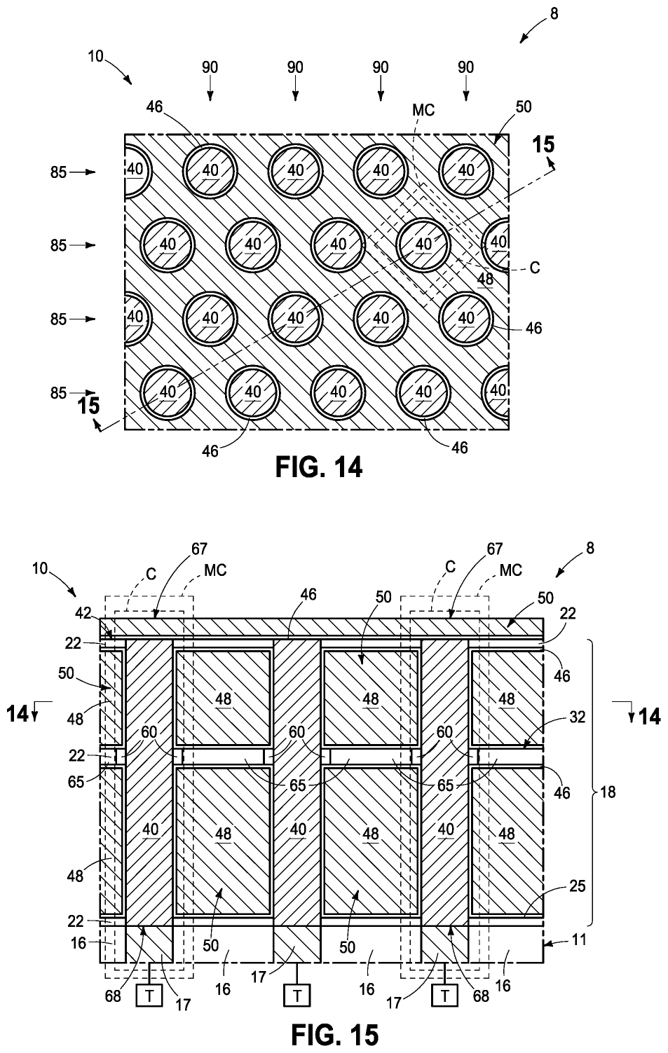

Referring to FIGS. 14 and 15, sacrificial material 20 (not shown) has been removed (e.g., by isotropic etching selectively relative to insulative material 22 and first capacitor electrodes 40). Where upper insulative lattice 42 is present, example openings 44 may be formed there-through (see FIG. 12) to provide access of the etching fluid to sacrificial material 20 there-below. Such openings may also be formed through insulative horizontal lattice 32 (not shown/viewable in the example figures). Thereafter, a capacitor insulator 46 is formed over first capacitor electrodes 40 and insulative horizontal lattice 32 (e.g., directly there-above and directly there-below; e.g., and over upper insulative lattice 42 and layer 25 when present). Thereafter, second-capacitor-electrode material 48 has been formed over capacitor insulator 46, thus forming a second capacitor electrode 50 and individual capacitors C (only a few being so designated) that comprise one of first capacitor electrodes 40, capacitor insulator 46, and second capacitor electrode 50. Example second capacitor electrode 50 is shown as being common to all capacitors C in array 10. Alternately, second-capacitor-electrode material 48 may be isolated (e.g., by masked anisotropic etching) to isolate individual second capacitor electrodes 50 to individual first capacitor electrodes 40 or to multiple of first capacitor electrodes 40 in array 10 that is less than all of such therein (neither being shown). Regardless, and in one embodiment, a memory array 10 has been formed that comprises memory cells MC (only a few being so designated) that individually comprise a capacitor C and a transistor T. In one embodiment and as shown, all of insulative lining 34 is removed (e.g., by isotropic etching) prior to forming capacitor insulator 46 (e.g., as shown by FIGS. 12 and 13).

In one embodiment, insulative horizontal lattice 32 comprises carbon (e.g., a carbon-doped insulative material, silicon carbonitride, etc. [i.e., regardless of stoichiometry/whether being stoichiometric]). Such insulative horizontal lattice 32 has less carbon, if any, immediately-laterally-adjacent individual of first capacitor electrodes 40 than laterally-distal therefrom (i.e., there being no insulative material 22 of insulative horizontal lattice 32 between first capacitor electrodes 40 and that which is immediately-laterally-adjacent thereto). For example, and by way of example only, insulative horizontal lattice 32 is shown as comprising individual regions 60 that are immediately-laterally-adjacent individual of first capacitor electrodes 40 and comprising regions 65 that are laterally-distal from first capacitor electrodes 40 (i.e., in comparison to individual regions 60). Such may result, by way of example only, from exposure of regions 60 to nitrogen-containing plasma 35 during deposition of insulative lining 34. Such may also occur with respect to layer 25 (if such comprises carbon and not shown). Example regions 60 individually comprise an annulus the diametrical expanse of such will depend on number of intermittent exposures, intensity, and/or time thereof. If regions 60 are formed in layer 25 or other insulative lattices 32 that are present and which comprise carbon (not shown), diametrical expanse will likely be less moving deeper into the stack.

In one embodiment, insulative horizontal lattice 32 immediately-laterally-adjacent individual first capacitor electrodes 40 is devoid of carbon (“devoid” herein meaning from 0 atoms/cm³ up to and including 1×10¹² atoms/cm³). In one embodiment, insulative horizontal lattice 32 immediately-laterally-adjacent individual first capacitor electrodes 40 comprises carbon at greater than 1×10¹² atoms/cm³. In one embodiment, insulative horizontal lattice 32 immediately-laterally-adjacent individual first capacitor electrodes 40 comprises from 10.0 atomic percent to 90.0 atomic percent (in one such embodiment from 40.0 atomic percent to 70.0 atomic percent) less carbon than atomic percentage of carbon of insulative horizontal lattice 32 that is laterally-distal therefrom.

Any other attribute(s) or aspect(s) as shown and/or described herein with respect to other embodiments may be used in the embodiments shown and described with reference to the above embodiments.

Intermittent exposure of insulative lining 34 to a nitrogen-containing plasma during its deposition may inhibit such deposition sufficient to reduce risk or degree of individual openings 30 being pinched-off (significantly narrowed) at their tops. Such may provide increase in margin and improved capacitor critical dimension.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, an array (e.g., 10) of capacitors (e.g., C) comprises a plurality of capacitors (e.g., C) individually comprising a first capacitor electrode (e.g., 40), a second capacitor electrode (e.g., 50), and a capacitor insulator (e.g., 46) between the first capacitor electrode and the second capacitor electrode. An insulative horizontal lattice (e.g., 32) is among the plurality of capacitors between a top (e.g., 67) and a bottom (e.g., 68) of individual of the capacitors. The capacitor insulator is directly above and directly below the insulative horizontal lattice between immediately-horizontally-adjacent of the capacitors. The insulative horizontal lattice comprises carbon. The insulative horizontal lattice has less carbon, if any, immediately-laterally-adjacent individual of the first capacitor electrodes than laterally-distal therefrom. Any other attribute(s) or aspect(s) as shown and/or described herein with respect to other embodiments may be used.

In one embodiment, an array (e.g., 10) of memory cells (e.g., MC) individually comprising a capacitor (e.g., C) above a transistor (e.g., T) comprises rows (e.g., 85) and columns (e.g., 90) of transistors (e.g., T). A gateline (e.g., WL) interconnects multiple of the transistors along individual of the rows. A digitline (e.g., 130 or 131) interconnects multiple of the transistors along individual of the columns. The transistors individually comprising a pair of source/drain regions (e.g., 70 and 72). One of the source/drain regions (e.g., 70) of the pair is electrically coupled (e.g., directly) with individual of the digitlines. The other of the source/drain regions (e.g., 72) of the pair is electrically coupled (e.g., directly) with a first capacitor electrode (e.g., 40) of one of a plurality of capacitors (e.g., C) that is above the transistors. The plurality of capacitors individually comprise the first capacitor electrode, a second capacitor electrode (e.g., 50), and a capacitor insulator (e.g., 46) between the first capacitor electrode and the second capacitor electrode. An insulative horizontal lattice (e.g., 32) is among the plurality of capacitors between a top (e.g., 67) and a bottom (e.g., 68) of individual of the capacitors. The capacitor insulator is directly above and directly below the insulative horizontal lattice between immediately-horizontally-adjacent of the capacitors. The insulative horizontal lattice comprises carbon. The insulative horizontal lattice has less carbon, if any, immediately-laterally-adjacent individual of the first capacitor electrodes than laterally-distal therefrom. Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of component s may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees therefrom) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “ elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming an array of capacitors comprises forming horizontally-spaced openings into sacrificial material and through insulative material that is between a top and bottom of the sacrificial material. The insulative material at least predominately comprises at least one of a silicon nitride, a silicon boronitride, and a silicon carbonitride. The insulative material with horizontally-spaced openings there-through comprises an insulative horizontal lattice. An insulative lining is deposited within the horizontally-spaced openings and directly above the sacrificial material. The insulative lining at least predominately comprises at least one of a silicon oxide and a silicon oxynitride. During the depositing, the insulative lining is intermittently exposed to a nitrogen-containing plasma. First capacitor electrodes that are individually within individual of the horizontally-spaced openings are formed laterally over the insulative lining that is in the horizontally-spaced openings. The sacrificial material is removed and a capacitor insulator is formed over the first capacitor electrodes and the insulative horizontal lattice. Second-capacitor-electrode material is formed over the capacitor insulator.

In some embodiments, an array of capacitors comprises a plurality of capacitors individually comprising a first capacitor electrode, a second capacitor electrode, and a capacitor insulator between the first capacitor electrode and the second capacitor electrode. An insulative horizontal lattice is among the plurality of capacitors between a top and a bottom of individual of the capacitors. The capacitor insulator is directly above and directly below the insulative horizontal lattice between immediately-horizontally-adjacent of the capacitors. The insulative horizontal lattice comprises carbon. The insulative horizontal lattice has less carbon, if any, immediately-laterally-adjacent individual of the first capacitor electrodes than laterally-distal therefrom.

In some embodiments, an array of memory cells individually comprising a capacitor above a transistor comprises rows and columns of the transistors. A gateline interconnects multiple of the transistors along individual of the rows. A digitline interconnects multiple of the transistors along individual of the columns. The transistors individually comprise a pair of source/drain regions. One of the source/drain regions of the pair is electrically coupled with individual of the digitlines. The other of the source/drain regions of the pair is electrically coupled with a first capacitor electrode of one of a plurality of capacitors that is above the transistors. The plurality of capacitors individually comprise the first capacitor electrode, a second capacitor electrode, and a capacitor insulator between the first capacitor electrode and the second capacitor electrode. An insulative horizontal lattice is among the plurality of capacitors between a top and a bottom of individual of the capacitors. The capacitor insulator is directly above and directly below the insulative horizontal lattice between immediately-horizontally-adjacent of the capacitors. The insulative horizontal lattice comprises carbon. The insulative horizontal lattice has less carbon, if any, immediately-laterally-adjacent individual of the first capacitor electrodes than laterally-distal therefrom.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming an array of capacitors, comprising:
forming horizontally-spaced openings into sacrificial material and through insulative material that is between a top and bottom of the sacrificial material; the insulative material at least predominately comprising at least one of a silicon nitride, a silicon boronitride, and a silicon carbonitride; the insulative material with horizontally-spaced openings there-through comprising an insulative horizontal lattice;
depositing an insulative lining within the horizontally-spaced openings and directly above the sacrificial material, the insulative lining at least predominately comprising at least one of a silicon oxide and a silicon oxynitride;
during the depositing, intermittently exposing the insulative lining to a nitrogen-containing plasma;
forming first capacitor electrodes that are individually within individual of the horizontally-spaced openings laterally over the insulative lining that is in the horizontally-spaced openings;
removing the sacrificial material and forming a capacitor insulator over the first capacitor electrodes and the insulative horizontal lattice; and
forming second-capacitor-electrode material over the capacitor insulator.

2. The method of claim 1 wherein the intermittently exposing results in less of the insulative lining being deposited directly above the sacrificial material than would otherwise occur under identical depositing conditions but for the intermittently exposing.

3. The method of claim 1 wherein the nitrogen-containing plasma is derived from at least one of N₂, NH₃, NF₃, and NOₓ.

4. The method of claim 1 wherein the insulative material and the insulative horizontal lattice at least predominately comprise the silicon nitride.

5. The method of claim 1 wherein the insulative material and the insulative horizontal lattice at least predominately comprise the silicon boronitride.

6. The method of claim 1 wherein the insulative material and the insulative horizontal lattice at least predominately comprise the silicon carbonitride.

7. The method of claim 6 wherein carbon content in the silicon carbonitride is 0.1 atomic percent to 30.0 atomic percent.

8. The method of claim 7 wherein carbon content in the silicon carbonitride is 5.0 atomic percent to 7.0 atomic percent.

9. The method of claim 1 wherein the insulative material and the insulative horizontal lattice at least predominately comprise at least two of the silicon nitride, the silicon boronitride, and the silicon carbonitride.

10. The method of claim 1 wherein the insulative lining at least predominately comprises the silicon oxide.

11. The method of claim 1 wherein the insulative lining at least predominately comprises the silicon oxynitride.

12. The method of claim 1 wherein the insulative lining is not deposited aside the insulative horizontal lattice.

13. The method of claim 1 wherein the insulative lining is deposited aside the insulative horizontal lattice.

14. The method of claim 1 comprising removing all of the insulative lining prior to forming the capacitor insulator.

15. The method of claim 1 wherein the insulative horizontal lattice comprises carbon; the insulative horizontal lattice having less carbon, if any, immediately-laterally-adjacent individual of the first capacitor electrodes than laterally-distal therefrom.

16. An array of capacitors, comprising:
a plurality of capacitors individually comprising a first capacitor electrode, a second capacitor electrode, and a capacitor insulator between the first capacitor electrode and the second capacitor electrode;
an insulative horizontal lattice among the plurality of capacitors between a top and a bottom of individual of the capacitors, the capacitor insulator being directly above and directly below the insulative horizontal lattice between immediately-horizontally-adjacent of the capacitors; and
the insulative horizontal lattice comprising carbon; the insulative horizontal lattice having less carbon, if any, immediately-laterally-adjacent individual of the first capacitor electrodes than laterally-distal therefrom.

17. The array of claim 16 wherein the insulative horizontal lattice immediately-laterally-adjacent the individual first capacitor electrodes is devoid of carbon.

18. The array of claim 16 wherein the insulative horizontal lattice immediately-laterally-adjacent the individual first capacitor electrodes comprises carbon at greater than 1×10¹² atoms/cm³.

19. The array of claim 18 wherein the insulative horizontal lattice immediately-laterally-adjacent the individual first capacitor electrodes comprises from 10.0 atomic percent to 90.0 atomic percent less carbon than atomic percentage of carbon of the insulative horizontal lattice that is laterally-distal therefrom.

20. An array of memory cells individually comprising a capacitor above a transistor, comprising;
rows and columns of transistors, a gateline interconnecting multiple of the transistors along individual of the rows, a digitline interconnecting multiple of the transistors along individual of the columns, the transistors individually comprising a pair of source/drain regions, one of the source/drain regions of the pair being electrically coupled with individual of the digitlines, the other of the source/drain regions of the pair being electrically coupled with a first capacitor electrode of one of a plurality of capacitors that is above the transistors;
the plurality of capacitors individually comprising the first capacitor electrode, a second capacitor electrode, and a capacitor insulator between the first capacitor electrode and the second capacitor electrode;
an insulative horizontal lattice among the plurality of capacitors between a top and a bottom of individual of the capacitors, the capacitor insulator being directly above and directly below the insulative horizontal lattice between immediately-horizontally-adjacent of the capacitors; and
the insulative horizontal lattice comprising carbon; the insulative horizontal lattice having less carbon, if any, immediately-laterally-adjacent individual of the first capacitor electrodes than laterally-distal therefrom.
